(19) United States
(12) Patent Application Publication
(10) Pub. No.: US 2026/0173356 A1
(43) Pub. Date: Jun. 18, 2026

(54) SEMICONDUCTOR STRUCTURE

(71) Applicant: Fujian Jinhua Integrated Circuit Co., Ltd., Quanzhou City (CN)

(72) Inventors: Daochu Wu, Quanzhou City (CN); Xiaoyan Chen, Quanzhou City (CN); Yirong Xu, Quanzhou City (CN); Chaozhen Hong, Quanzhou City (CN); Li-Wei Feng, Quanzhou City (CN)

(73) Assignee: Fujian Jinhua Integrated Circuit Co., Ltd., Quanzhou City (CN)

(21) Appl. No.: 19/236,965

(22) Filed: Jun. 12, 2025

(30) Foreign Application Priority Data
Dec. 17, 2024 (CN) 202411864475.5

(51) Int. Cl. H10B 12/00

(52) U.S. Cl. CPC H10B 12/485; H10B 12/0335; H10B 12/315; H10B 12/34; H10B 12/482

(57) ABSTRACT

A semiconductor structure includes a substrate having active regions, gate structures extending along a first direction and intersecting the active regions to divide each active region into a middle portion and two end portions, bit line structures extending along a second direction and electrically connected to the middle portions of the active regions. The first direction and the second direction are perpendicular. An outside part of the bit line structures includes a first bit line structure. An inside part of the bit line structures includes a second bit line structure. A plurality of first contact structures and second contact structures are alternatively and separately disposed at an outer side of the first bit line structure along the second direction and electrically connected to the end portions of the active regions. Bottom portions of the first contact structures are lower than bottom portions of the second contact structures.

### CROSS REFERENCE TO RELATED APPLICATION

This application claims the benefit of Chinese Patent Application No. 202411864475.5 filed on Dec. 17, 2024, which is incorporated herein by reference.

### BACKGROUND OF THE INVENTION

### 1. Field of the Invention

The present invention generally relates to a semiconductor structure, and more particularly, to a semiconductor structure with contact structures.

### 2. Description of the Prior Art

A dynamic random access memory (DRAM) is a kind of volatile memory, which includes a cell region including a plurality of memory cells and a peripheral region including a control circuit. Each memory cell includes a transistor and a capacitor electrically connected to the transistor. The transistor controls storage or release of charges into or from the capacitor for data storage. The control circuit addresses each memory cell to control data access through word lines (WL) and bit lines (BL) that are arranged over the cell region and are electrically connected to the memory cells.

In order to obtain enhanced chip density, the structure of the memory cells has been developed towards a three-dimensional designs involving buried word lines and stacked capacitors, wherein the stacked capacitors are disposed above the substrate and electrically connected to the transistors in the substrate in a vertical direction through contact structures and contact pads. This approach saves substrate area occupied by the capacitors and makes it easier to increase the capacitance by increasing the height of the electrode plates of the capacitors. However, there are still some technical issues that need further improvement.

### SUMMARY OF THE INVENTION

An object of an embodiment of the present invention is to provide a semiconductor structure including contact structures having different depths, which may improve the contact quality between the contact structures and the active regions of the transistors.

According to an embodiment of the present invention, a semiconductor structure includes a substrate comprising a plurality of active regions, a plurality of gate structures extending along a first direction and intersecting the plurality of active regions to divide each of the plurality of active regions into a middle portion and two end portions, a plurality of bit line structures extending along a second direction and electrically connected to the middle portions of the active regions, wherein the first direction and the second direction are perpendicular, an outside part of the plurality of bit line structures comprises a first bit line structure, an inside part of the plurality of bit line structures comprises a second bit line structure, and a plurality of first contact structures and a plurality of second contact structures alternatively and separately disposed at an outer side of the first bit line structure along the second direction and electrically connected to the end portions of the active regions, wherein bottom portions of the first contact structures are lower than bottom portions of the second contact structures.

According to an embodiment of the present invention, a semiconductor structure includes a substrate comprising a plurality of active regions, a plurality of gate structures extending along a first direction and intersecting the plurality of active regions, a plurality of spacer structures disposed on the gate structures, and a plurality of first contact structures and a plurality of second contact structures alternatively disposed between the spacer structures along a second direction and electrically connected to the active regions, wherein bottom portions of the first contact structures are lower than bottom portions of the second contact structures.

According to an embodiment of the present invention, a semiconductor structure includes a substrate comprising a plurality of active regions, a plurality of gate structures extending along a first direction and intersecting the plurality of active regions, a plurality of bit line structures extending along a second direction and electrically connected to the active regions, wherein the first direction and the second direction are perpendicular, an outside part of the plurality of bit line structures comprises a first bit line structure, an inside part of the plurality of bit line structures comprises a second bit line structure, at lease a first contact structure disposed at an outer side of the first bit line structure, and a plurality of third contact structures disposed at an inner side of the first bit line structure and between the second bit line structures, and aligned to the first contact structure along the first direction, wherein in a cross-sectional view, a bottom portion of the first contact structure is lower than bottom portions of the third contact structures, and a width of the first contact structure is larger than a width of the third contact structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 16 are schematic drawings illustrating intermediates of a semiconductor structure in a manufacturing process according to an embodiment of the present invention, wherein:

FIG. 1, FIG. 7 and FIG. 12 are plan views of the semiconductor structure;

FIG. 2, FIG. 3, FIG. 4, and FIG. 5 are cross-sectional views of the semiconductor structure along the line AA as illustrated in FIG. 1;

FIG. 6 is a cross-sectional view of the semiconductor structure along the line BB as illustrated in FIG. 1;

FIG. 8 is a cross-sectional view of the semiconductor structure along the line AA as illustrated in FIG. 7;

FIG. 9 is a cross-sectional view of the semiconductor structure along the line BB as illustrated in FIG. 7;

FIG. 10 is a cross-sectional view of the semiconductor structure along the line CC as illustrated in FIG. 7;

FIG. 11 is a cross-sectional view of the semiconductor structure along the line DD as illustrated in FIG. 7;

FIG. 13 is a cross-sectional view of the semiconductor structure along the line AA as illustrated in FIG. 12;

FIG. 14 is a cross-sectional view of the semiconductor structure along the line BB as illustrated in FIG. 12;

FIG. 15 is a cross-sectional view of the semiconductor structure along the line CC as illustrated in FIG. 12; and

FIG. 16 is a cross-sectional view of the semiconductor structure along the line DD as illustrated in FIG. 12.

### DETAILED DESCRIPTION

In the following description, preferred embodiments are presented in detail, accompanied by drawings, to help those skilled in the art to better understand the technical features and effects of this invention. In addition, the technical features in different embodiments may be replaced, recombined, or mixed with one another to constitute another embodiment without departing from the spirit of the present disclosure.

To facilitate understanding and simplify the drawing, several drawings depict only a portion of the semiconductor structure, and the specific components in the drawing are not drawn to scale. Additionally, the numbers and dimensions of the components in the drawings are for illustrative purpose only and should not be considered as limitations to the scope of this invention. It is understood by those skilled in the art that the terms such as “on”, “above”, “below”, “upper”, “lower”, “over”, “under”, etc. are used to indicate the relative positions of the components, and all the components may be turned over while still presenting the same structure. Both configurations are within the scope of this invention.

To facilitate the understanding the semiconductor structure of this invention, spatial reference directions are defined in the drawings, which include the first direction D1, the second direction D2, the third direction D3 and the fourth direction D4. The first direction D1, the second direction D2 and the third direction D3 are parallel to a surface of the substrate 100, and the first direction D1 and the second direction D2 are perpendicular to each other and both different from the third direction D3. The angle between the second direction D2 and the third direction D3 may be between 15 degrees and 75 degrees, but it is not limited thereto. The fourth direction D4 is perpendicular to the surface of the substrate 100. The first direction D1, the second direction D2 and the third direction D3 are referred to as horizontal directions. The fourth direction D4 is referred to as the vertical direction.

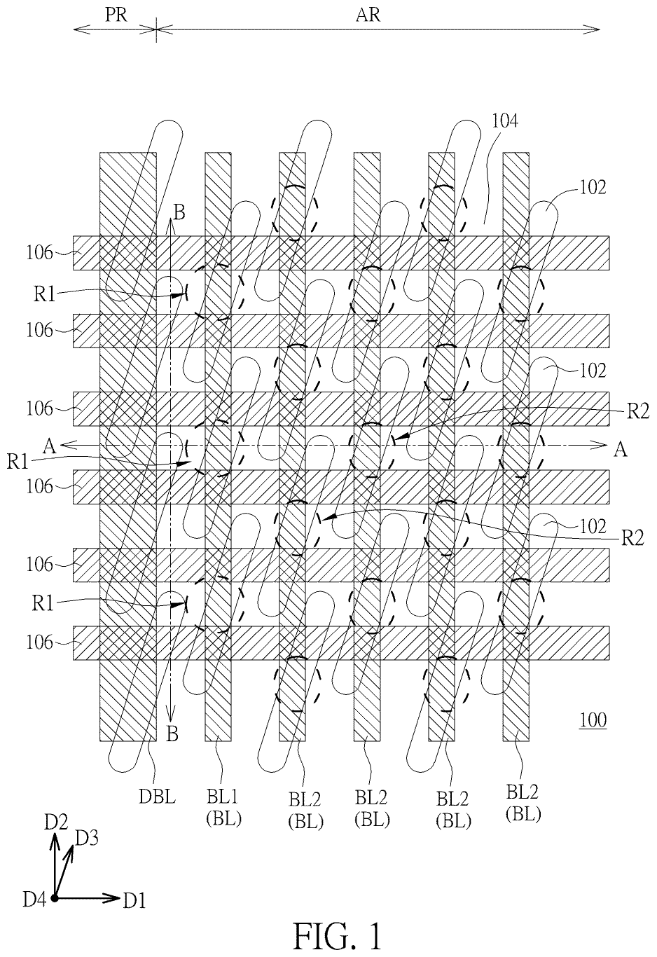

FIG. 1 to FIG. 16 are schematic drawings illustrating intermediates of a semiconductor structure in a manufacturing process according to an embodiment of the present invention. The drawings may omit some components of the semiconductor structure for simplicity. The semiconductor structure of the present invention may be used to fabricate dynamic random access memory (DRAM) including stacked capacitors. The semiconductor structure of the present invention may also be used to manufacture other types of semiconductor devices without departing from the scope of the present invention.

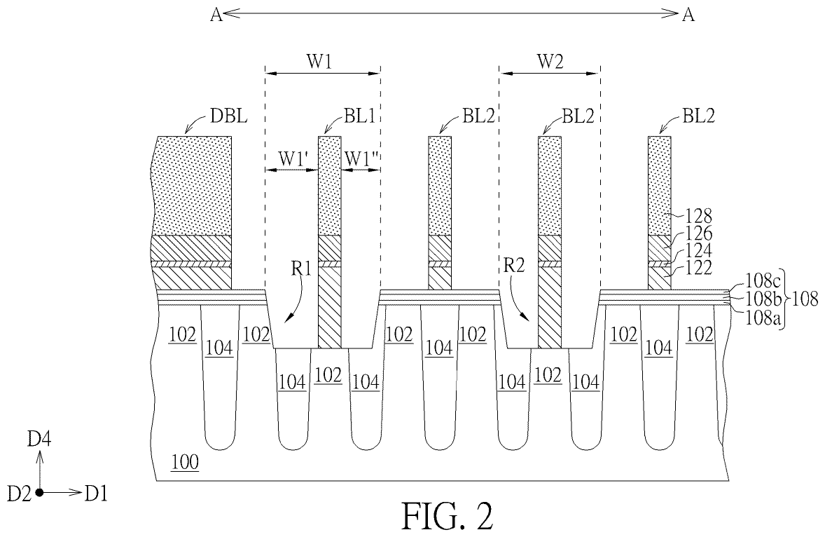

Please refer to FIG. 1 and FIG. 2. A substrate 100 is provided. The substrate 100 may be, for example, but not limited to, a silicon substrate, an epitaxial silicon substrate, a silicon germanium substrate, a silicon carbide substrate, or a silicon-on-insulator (SOI) substrate. The substrate 100 includes an array region AR and a peripheral region PR. The array region AR may also be referred to as a cell region, which is the region where the memory cells are formed. The memory cells may be dynamic random access memory cells. The peripheral region PR is adjacent to the outer side of the array region AR, serving to separate the array region AR from other circuit regions on the substrate 100. According to an embodiment of the present invention, the peripheral region PR may include various peripheral circuits, such as drivers, buffers, amplifiers, and decoders, but is not limited thereto.

The substrate 100 includes isolation structures 104 and a plurality of active regions 102 defined in the substrate 100 by the isolation structures 104. The isolation structures 104 may be shallow trench isolation (STI) structures that include single or multiple dielectric layers made of silicon dioxide (SiO₂), silicon nitride (SiN), silicon oxynitride (SiON), silicon carbonitride (SiCN), or a combination thereof, but is not limited thereto. The active regions 102 are separated from each other by the isolation structures 104, and are elongated along a third direction D3. The active regions 102 are arranged in a staggered configuration along a second direction D2 and a first direction D1 to form an array.

A plurality of gate structures 106 are disposed on the substrate 100, extending along the first direction D1 and parallel to each other along the second direction D2. The gate structures 106 intersect the active regions 102 to divide each active region 102 into two end portions and a middle portion. The portions of the gate structures 106 that intersect the active regions 102 function as the control gates for the transistors of the memory cells. The portions of the gate structures 106 that intersect the isolation structures 104 function as passing gates.

According to an embodiment of the present invention, the manufacturing steps of the gate structures 106 may include forming a plurality of gate trenches in the substrate 100 that cut through the isolation structures 104 and the active regions 102, forming a gate dielectric layer 132 along the bottom surface and sidewalls of each gate trench, forming a metal layer 134 on the gate dielectric layer 132 and filling a lower portion of each of the gate trenches, and then forming an insulating cap layer 138 on the metal layer 134 and filling the upper portion of each of the gate trenches. The insulating cap layer 138 and the gate dielectric layer 132 may include dielectric materials, such as silicon dioxide (SiO₂), silicon nitride (SiN), silicon oxynitride (SiON), silicon carbonitride (SiCN), or combinations thereof, but are not limited thereto. The metal layer 134 may include low-resistance metals, such as tungsten (W), copper (Cu), aluminum (Al), titanium (Ti), tantalum (Ta), titanium nitride (TiN), or compounds, alloys, and/or composite layers of the above materials, but are not limited thereto. According to an embodiment of the present invention, a polysilicon layer 136 may be disposed between the metal layer 134 and the insulating cap layer 138 to adjust the conductivity of the gate structures 106.

Subsequently, an insulating pad layer 108 is formed on the substrate 100. Subsequently, an etching process is performed to form a plurality of first recesses R1 and a plurality of second recesses R2 in the array region AR of the substrate 100, and extend through the insulating pad layer 108 to expose the middle portions of the active regions 102. After that, a bit line stack material layer (not shown) is formed on the substrate 100, filling the first recesses R1 and the second recesses R2. An etching process is performed to remove the excess portions of the bit line stack material layer, thereby patterning the bit line stack material layer into a plurality of bit line structures BL and at least a dummy bit line structure DBL.

According to an embodiment of the present invention, the insulating pad layer 108 may be a composite layer, such as an ONO composite layer composed of a silicon dioxide layer 108a, a silicon nitride layer 108b, and a silicon dioxide layer 108c, but is not limited thereto.

The first recesses R1 are formed in the outside part of the array region AR. The second recesses R2 are formed in the inside part of the array region AR. The first recesses R1 and the second recesses R2 have approximately circular or elliptical shapes in the plan view. The first recesses R1 have a width W1 along the first direction D1. The second recesses R2 have a width W2. The width W1 is larger than the width W2. The first recesses R1 are offset toward the peripheral region PR. As a result, the middle portions of the active regions 102 exposed from the first recesses R1 are situated closer to the side of each first recess R1 that is opposite to the peripheral region PR, rather than being located at the center of the first recess R1. According to an embodiment of the present invention, the depths of the first recesses R1 and the second recesses R2 are approximately the same.

The bit line structures BL are disposed on the array region AR of the substrate 100, extending along the second direction D2 and arranged parallel to each other along the first direction D1. Each bit line structure BL includes, from bottom to top, a semiconductor layer 122, an interface layer 124, a metal layer 126, and a hard mask layer 128. The semiconductor layer 122 may include crystalline silicon, polycrystalline silicon, amorphous silicon, doped silicon, silicon-germanium (SiGe), or other suitable semiconductor materials, but is not limited thereto. The interface layer 124 may include metals, metal silicides, or metal nitrides, such as titanium (Ti), titanium nitride (TiN), tungsten silicide (WSi), cobalt silicide (CoSi), tungsten nitride (WN), but is not limited thereto. The metal layer 126 may include tungsten (W), copper (Cu), aluminum (Al), titanium (Ti), tantalum (Ta), or compounds, alloys, and/or composite layers of the above metal materials, but is not limited thereto. The hard mask layer 128 may include dielectric materials such as silicon dioxide (SiO₂), silicon nitride (SiN), silicon oxynitride (SiON), silicon carbonitride (SiCN), or a combination of the above materials, but is not limited thereto. According to an embodiment of the present invention, the semiconductor layer 122 includes polysilicon, the interface layer 124 includes tungsten silicide (WSi), the metal layer 126 includes tungsten (W), and the hard mask layer 128 includes silicon nitride (SiN). The outside part of the bit line structures BL adjacent to the peripheral region PR includes at least a first bit line structure BL1. The inside part of the bit line structures BL away from the peripheral region PR includes a plurality of second bit line structures BL2. The first bit line structure BL1 is in direct contact with the middle portions of the active regions 102 exposed from the first recesses R1. The second bit line structures BL2 are in direct contact with the middle portions of the active regions 102 exposed from the second recesses R2. As shown in FIG. 2, the first recesses R1 are slightly offset towards the peripheral region PR, so that the width W1′ of the portion of the first recesses R1 exposed from the outer side of the first bit line structure BL1 would be larger than the width W1″ of the portion of the first recesses R1 exposed from the inner side of the first bit line structure BL1.

The dummy bit line structure DBL is disposed on the peripheral region PR of the substrate 100 adjacent to the outer side of the first bit line structure BL1. The dummy bit line structure DBL extends along the second direction D2 and crosses over the active regions 102 in the peripheral region PR. The dummy bit line structure DBL has the same stack structure and materials as the bit line structures BL. The active regions 102 in the peripheral region PR are physically separately and electrically isolated from the dummy bit line structure DBL by the insulating pad layer 108.

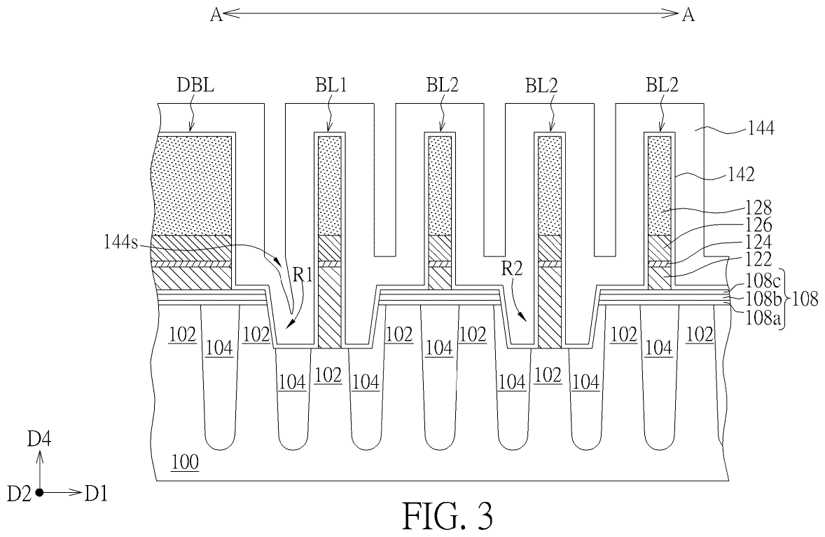

Please refer to FIG. 3. A first insulating layer 142 and a second insulating layer 144 are sequentially formed to conformally cover the insulating pad layer 108, the first recesses R1, the second recesses R2, and the top surfaces and sidewalls of the bit line structures BL and the dummy bit line structure DBL. The first insulating layer 142 and the second insulating layer 144 include different dielectric materials selected from silicon dioxide (SiO₂), silicon nitride (SiN), silicon oxynitride (SiON), silicon carbonitride (SiCN), or a combination of the above materials, but are not limited thereto. According to an embodiment of the present invention, the first insulating layer 142 includes silicon nitride (SiN), and the second insulating layer 144 includes silicon dioxide (SiO₂). The thickness of the second insulating layer 144 must be controlled to ensure that the portions of the second recesses R2 exposed from two sides of the second bit line structures BL2 and the portions of the first recesses R1 exposed from the inner side of the first bit line structure BL1 are completely filled by the second insulating layer 144. However, the portions of the first recesses R1 exposed from the outer side of the first bit line structure BL1 are not completely filled, resulting in a gap 144s formed therein.

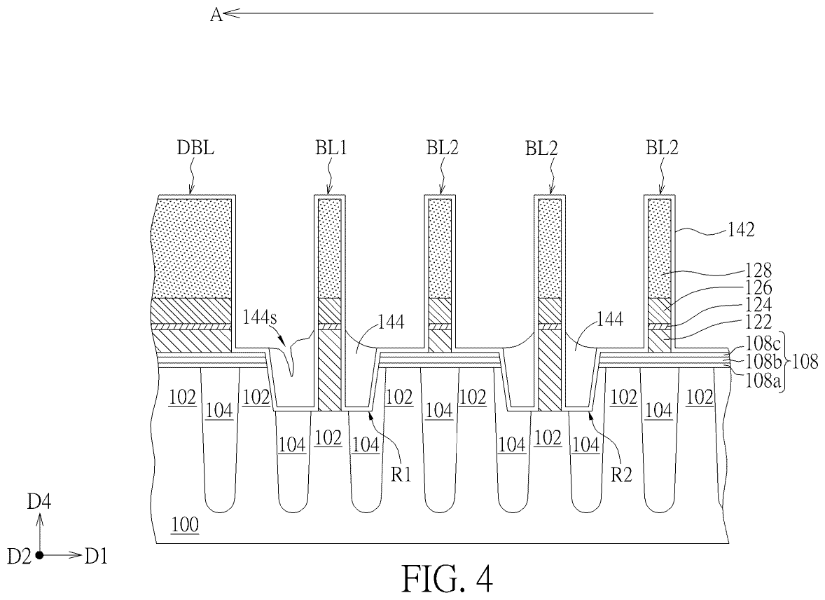

Please refer to FIG. 4. An etching process is performed to remove a portion of the second insulating layer 144, thereby exposing the first insulating layer 142 on the top surfaces and sidewalls of the dummy bit line structure DBL, the first bit line structure BL1, and the second bit line structures BL2 and the insulating layer 108. The portions of the first recesses R1 and second recesses R2 exposed from two sides of the first bit line structure BL1 and the second bit line structures BL2 are still filled by the second insulating layer 144.

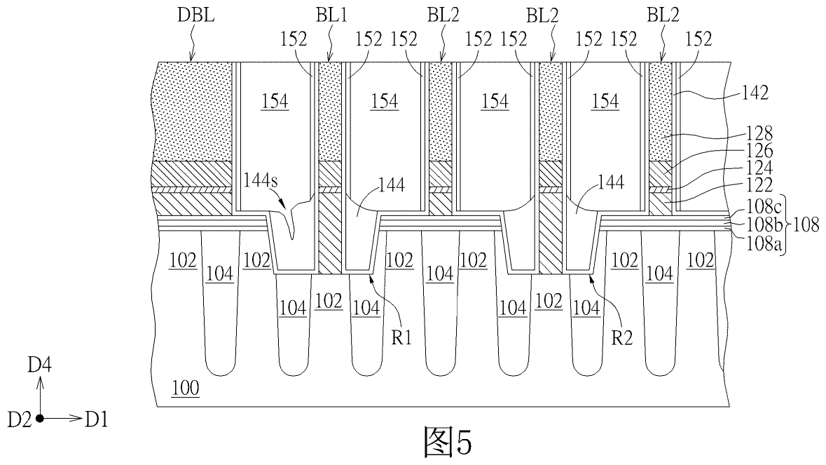

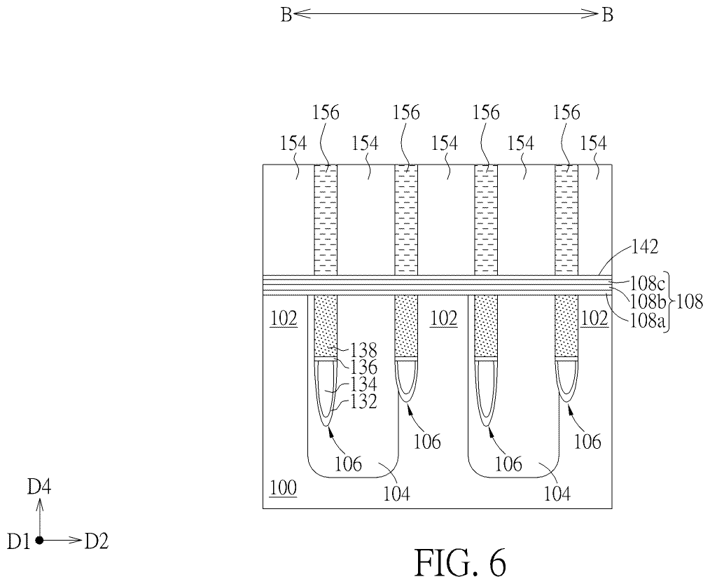

Please refer to FIG. 5 and FIG. 6. A third insulating layer 152 is formed on the sidewalls of the dummy bit line structure DBL, the first bit line structure BL1, and the second bit line structures BL2. Subsequently, a dielectric layer 154 is deposited to fill the spaces between the dummy bit line structure DBL, the first bit line structure BL1, and the second bit line structures BL2. Portions of the dielectric layer 154 over the gate structure 106 are then selectively etched away and replaced with the isolation spacers 156, resulting in the structure depicted in FIG. 6, where the remaining portions of the dielectric layer 154 and the isolation spacers 156 are alternately arranged between the dummy bit line structure DBL, the first bit line structure BL1, and the second bit line structures BL2. The third insulating layer 152, the dielectric layer 154, and the isolation spacers 156 are made of dielectric materials, such as silicon dioxide (SiO₂), silicon nitride (SiN), silicon oxynitride (SiON), silicon carbonitride (SiCN), or combinations of the above materials, but are not limited thereto. According to an embodiment of the present invention, the material of the third insulating layer 152 includes silicon nitride (SiN), the material of the dielectric layer 154 includes silicon dioxide (SiO₂), and the material of the isolation spacers 156 includes silicon nitride (SiN).

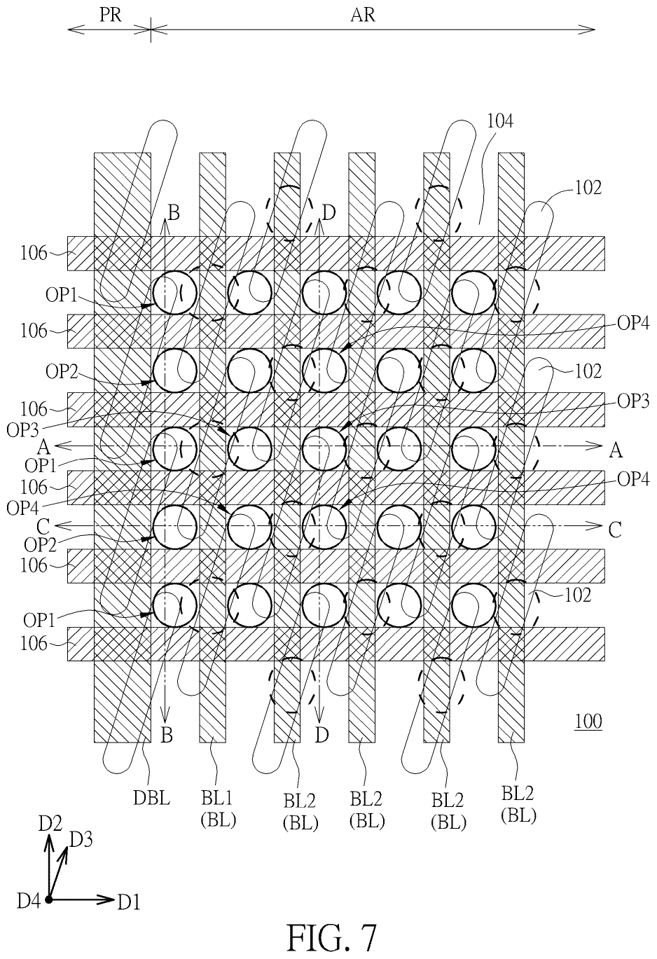

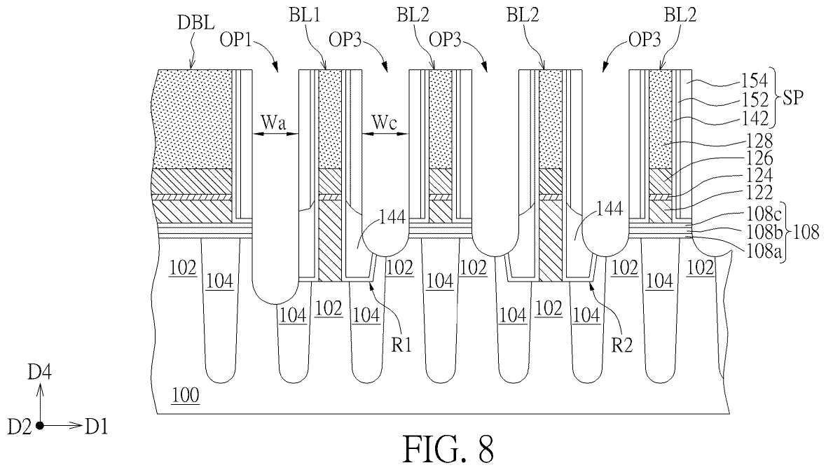

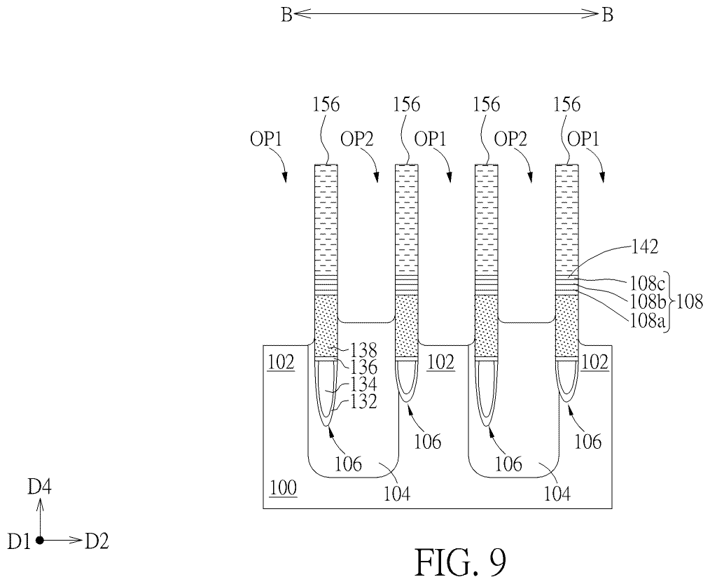

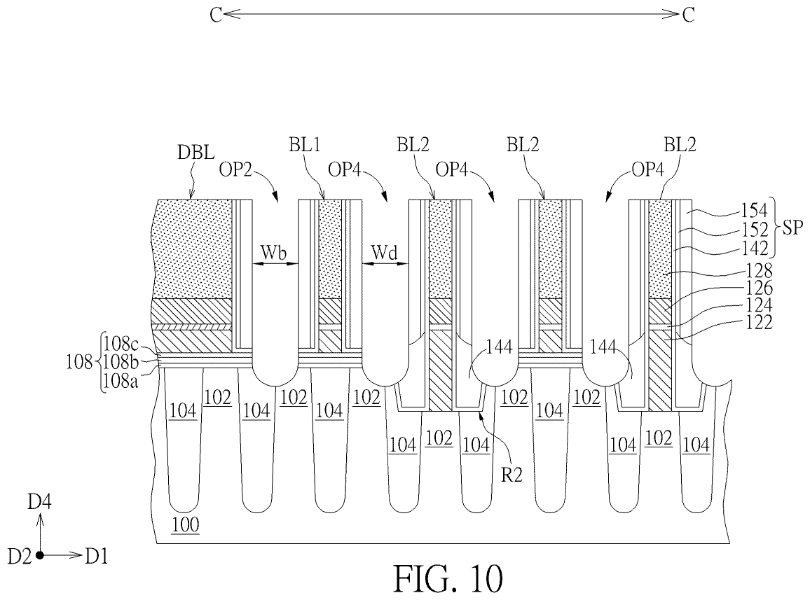

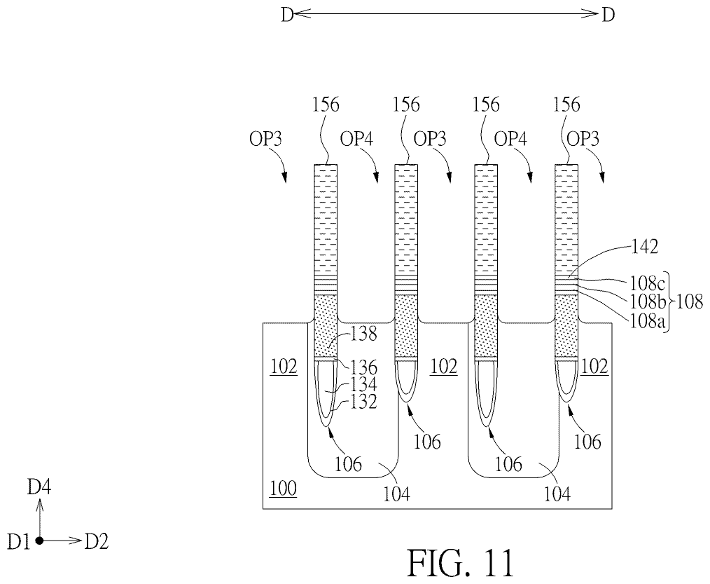

Please refer to FIG. 7, FIG. 8, FIG. 9, FIG. 10, and FIG. 11. Subsequently, using the isolation spacers 156 and the hard mask layer 128 as a mask, an etching process is performed to remove a portion of the dielectric layer 154 to form a plurality of openings located between the dummy bit line structure DBL, the first bit line structure BL1, and the second bit line structure BL2 and separated from each other by the isolation spacers 156. Following, another etching process is performed, through the openings to etch the first insulating layer 142, the insulating pad layer 108, the second insulating layer 144, and the active regions 102, thereby forming a plurality of contact holes. The contact holes includes first contact holes OP1 and second contact holes OP2 that are alternately arranged between the outer side of the first bit line structure BL1 and the dummy bit line structure DBL along the second direction D2, and a plurality of third contact holes OP3 and a plurality of fourth contact holes OP4 that are alternately arranged between the inner side of the first bit line structure BL1 and one of the second bit line structures BL2 and between adjacent second bit line structures BL2 along the second direction D2. According to one embodiment of this invention, a portion of the dielectric layer 154 may remain on the sidewalls of the dummy bit line structure DBL, the first bit line structure BL1, and the second bit line structures BL2, forming sidewall structures SP in conjunction with the first insulating layer 142 and the second insulating layer 144.

The first contact holes OP1 and the third contact holes OP3 are aligned along the first direction D1. The first contact holes OP1 respectively have one side that partially overlaps with an end portion of the active regions 102 crossed by the dummy bit line structure DBL, while the opposite side partially overlaps with one of the first recesses R1. The third contact holes OP3 respectively have one side that partially overlaps with an end portion of the active regions 102 crossed by the second line structures BL2. The opposite side of the third contact holes OP3 adjacent to the first bit line structure BL1 partially overlaps with one of the first recesses R1, while the opposite side of the third contact holes OP3 between the second line structures BL2 partially overlaps with the second recesses R2. The first contact holes OP1 each have a width Wa along the first direction D1. The third contact holes OP3 each have a width We along the first direction D1. According to an embodiment of the present invention, Wa is larger than Wc.

The second contact holes OP2 and the fourth contact holes OP4 are aligned along the first direction D1. The second contact holes OP2 respectively have one side that partially overlaps with an end portion of the active regions 102 crossed by the first bit line structure BL1, while the opposite side partially overlaps with a middle portion of the active regions 102 crossed by the dummy bit line structure DBL. The fourth contact holes OP4 respectively have one side that partially overlaps with an end portion of the active regions crossed by the second bit line structures BL2, while the opposite side partially overlaps with one of the second recesses R2. Each of the second contact holes OP2 has a width Wb along the first direction D1. Each of the fourth contact holes OP4 has a width Wd along the first direction D1. According to an embodiment of the present invention, Wb is larger than Wd. According to an embodiment of the present invention, Wb, We, and Wd are approximately the same. According to an embodiment of the present invention, Wa is larger than Wb, We, and Wd, respectively.

It is noteworthy that the gap 144s formed in the second insulating layer 144 (as shown in FIG. 5) allows the etchant used in the etching process to penetrate more deeply and easily. As a result, the depth of the first contact holes OP1 is larger than the depths of the second contact holes OP2, the third contact holes OP3, and the fourth contact holes OP4. According to an embodiment of the present invention, as illustrated in FIG. 8 and FIG. 10, the bottom portions of the second contact holes OP2, the third contact holes OP3, and the fourth contact holes OP4 are lower than the bottom surface of the insulating pad layer 108 and not lower than the bottom portions of the first recesses R1 and the second recesses R2. The bottom portions of the first contact holes OP1 are lower than the bottom surfaces of the first recesses R1. According to an embodiment of the present invention, as illustrated in FIG. 9 and FIG. 11, the bottom portions of the first contact holes OP1, the second contact holes OP2, the third contact holes OP3, and the fourth contact holes OP4 are all higher than the top surface of the metal layer 134 of the gate structures 106. According to an embodiment of the present invention, as illustrated in FIG. 10 and FIG. 11, the depths of the second contact holes OP2 and the fourth contact holes OP4 are approximately the same.

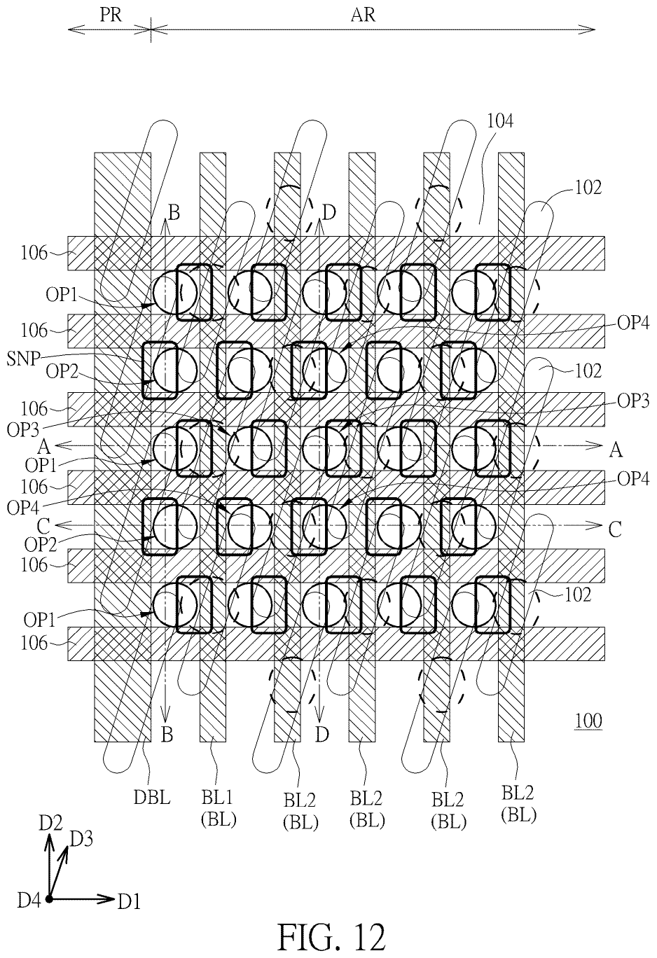

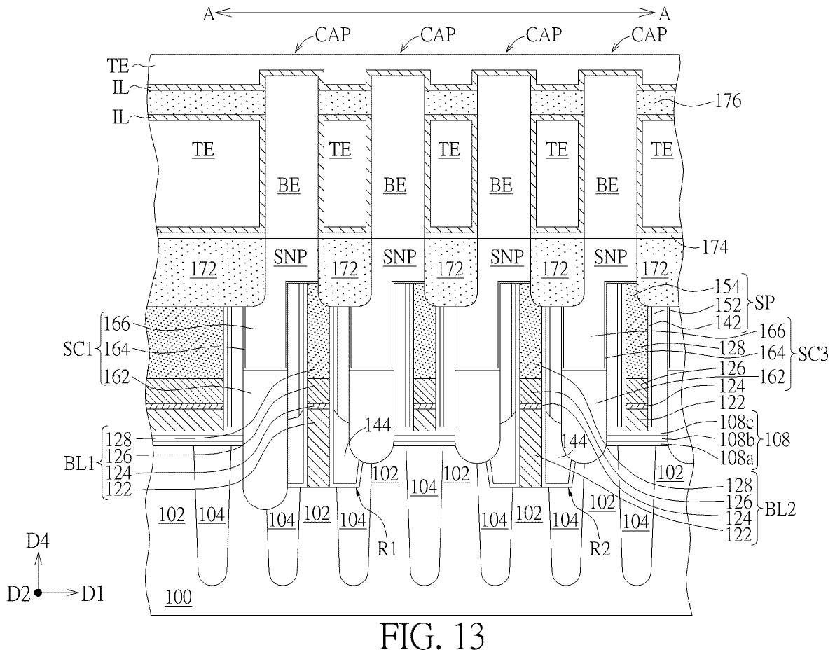

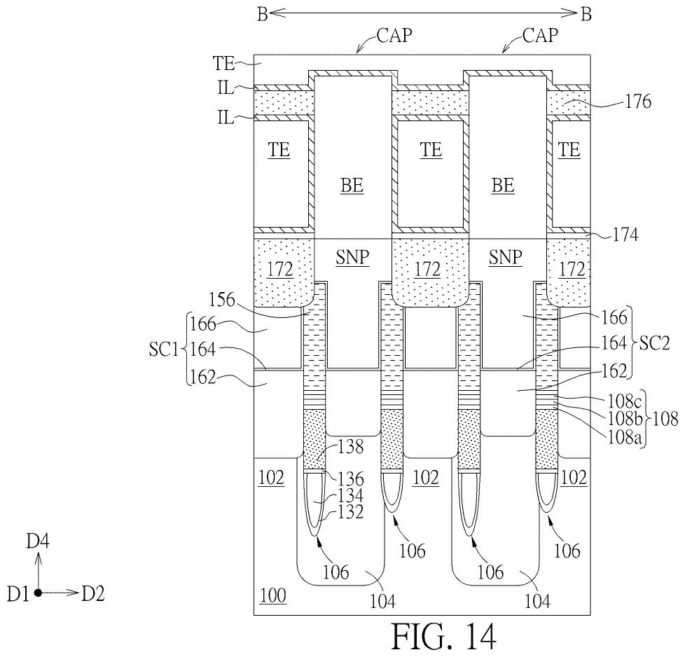

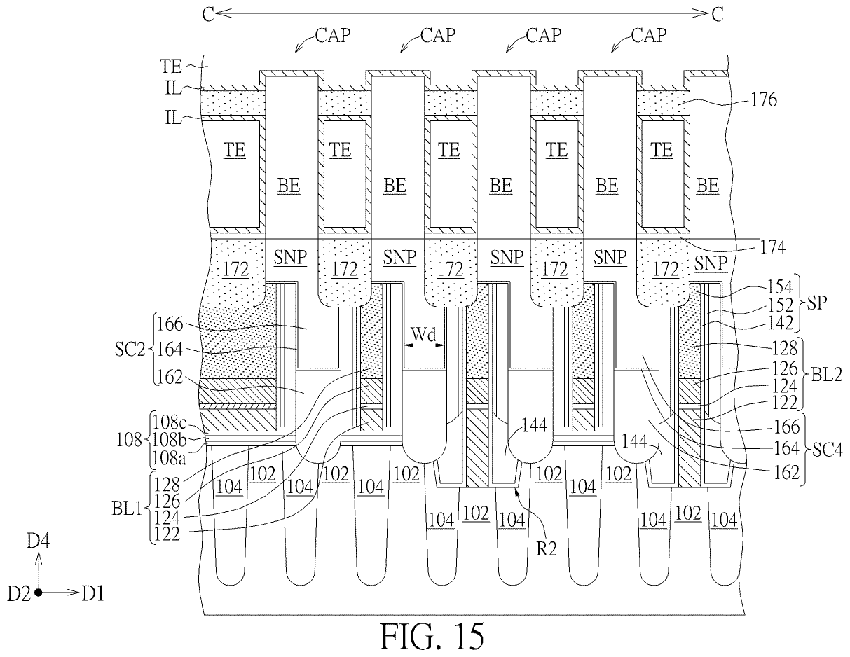

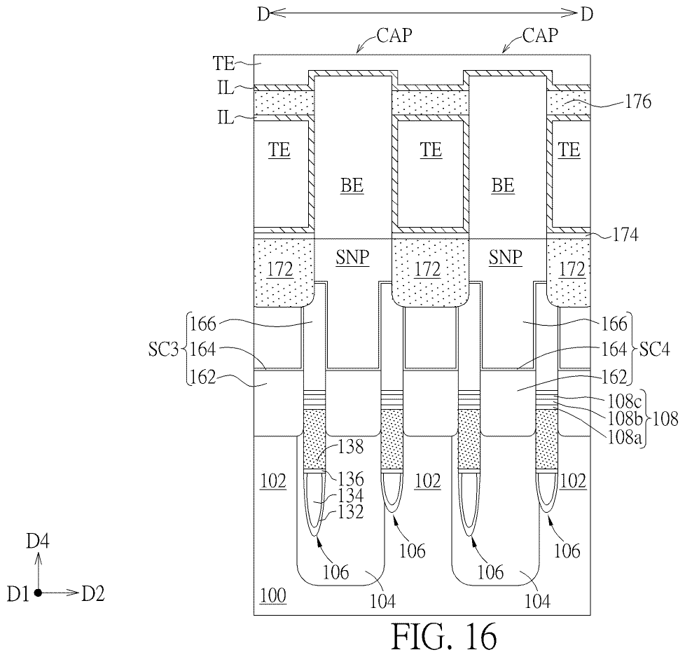

Please refer to FIG. 12, FIG. 13, FIG. 14, FIG. 15, and FIG. 16. A contact material layer 162 is subsequently formed to fill the lower portions of the first contact holes OP1, the second contact holes OP2, the third contact holes OP3, and the fourth contact holes OP4. A barrier layer 164 is then conformally deposited on the top surface of the contact material layer 162, the sidewalls of the first contact holes OP1, the second contact holes OP2, the third contact holes OP3, and the fourth contact holes OP4, the sidewall structures SP, the top surface of the dummy bit line structure DBL, the top surface of the first bit line structure BL1, and the top surfaces of the second bit line structures BL2. After that, a conductive layer 166 is formed on the barrier layer 164, filling the upper portions of the first contact holes OP1, the second contact holes OP2, the third contact holes OP3, and the fourth contact holes OP4. An etching process is then performed to remove the excess portions of the conductive layer 166 and the barrier layer 164 outside the first contact holes OP1, the second contact holes OP2, the third contact holes OP3 and the fourth contact holes OP4, thereby forming a plurality of contact structures, specifically the first contact structures SC1, the second contact structures SC2, the third contact structures SC3 and the fourth contact structures SC4, which are respectively located in the first contact holes OP1, the second contact holes OP2, the third contact holes OP3, and the fourth contact holes OP4. Additionally, a plurality of contact pads SNP are also formed on the contact structures. The shapes and dimensions of the contact structures are determined by the shapes and dimensions of the contact holes. Accordingly, the first contact structures SC1 have the width Wa, the second contact structures SC2 have the width Wb, the third contact structures SC3 have the width Wc, and the fourth contact structures SC4 have the width Wd.

The first contact structures SC1, the second contact structures SC2, the third contact structures SC3, and the fourth contact structures SC4 respectively include a lower portion made of the contact material layer 162 and an upper portion made of the conductive layer 166 and the barrier layer 164 along the bottom surface and sidewalls of the conductive layer 166. The contact material layer 162 may include semiconductor materials such as crystalline silicon, poly silicon, amorphous silicon, doped silicon, silicon-germanium (SiGe), or combinations of the above materials, but are not limited thereto. The barrier layer 164 and the conductive layer 166 may respectively include tungsten (W), titanium (Ti), nitride, silicide, or alloys, combinations, composite layers of the above materials, but are not limited thereto. According to an embodiment of the present invention, the contact material layer 162 includes phosphorus (P) doped silicon, the barrier layer 164 includes titanium nitride (TiN), and the conductive layer 166 includes tungsten (W). The contact pads SNP are respectively integrally formed with the conductive layers 166 of the first contact structures SC1, the second contact structures SC2, the third contact structures SC3, and the fourth contact structures SC4, and include the same materials. According to an embodiment of the present invention, as illustrated in FIG. 12, the contact pads SNP are aligned along the first direction D1 and staggered along the second direction D2, and partially overlap with the dummy bit line structure DBL, the first bit line structure BL1 and the second bit line structures BL2. The contact pads SNP may partially overlap the isolation spacers 156 over the gate structures 106 to achieve higher pattern density of the contact pads SNP and larger process window for subsequent fabrication of the bottom electrodes BE of the capacitor structures CAP (shown in FIG. 14) for improved electrical interconnection between the bottom electrodes BE and the contact pads SNP.

At this point, the semiconductor structure of this embodiment has been obtained. As illustrated in FIG. 12, FIG. 13, FIG. 14, FIG. 15, and FIG. 16, the semiconductor structure includes a substrate 100 having an array region AR and a peripheral region PR. A plurality of active regions 102 are formed in the array region AR and the peripheral region PR. A plurality of gate structures 106 extend parallel to each other along the first direction D1 through the array region AR and the peripheral region PR, intersect the active regions 102 to divide each active region 102 into a middle portion and two end portions. A plurality of bit line structures BL are arranged on the array region AR, extending parallel to each other along the second direction D2 and crossing the middle portions of the active regions 102, and are in direct contact and electrically connected to the middle portions of the active regions 102. The first direction D1 and the second direction D2 are perpendicular to each other. The outside part of the bit line structures BL adjacent to the peripheral region PR includes at least a first bit line structure BL1. The inside part of the bit line structures BL away from the peripheral region PR includes a plurality of second bit line structures BL2. A dummy bit line structure DBL is disposed on the peripheral region PR of the substrate 100, extending along the second direction D2 and crossing the middle portions of the active regions 102, and is physically separated and electrically isolated from the active regions 102 by the insulating pad layer 108. A plurality of first contact structures SC1 and second contact structures SC2 are alternatively and separately arranged between the outer side of the first bit line structure BL1 and the dummy bit line junction DBL along the second direction D2, and are electrically connected to the end portions of the active regions 102. A plurality of third contact structures SC3 and fourth contact structures SC4 are alternatively and separately arranged along the second direction D2 between the inner side of the first bit line structure BL1 the adjacent second bit line structure BL2, and are electrically connected to the end portions of the active regions 102. The third contact structures SC3 and the first contact structures SC1 are aligned along the first direction D1. The fourth contact structures SC4 and the second contact structures SC2 are aligned along the first direction D1. Due to the gap 144s (as shown in FIG. 5) formed at the expected locations of the first contact holes OP1 facilitates deeper etching, the first contact holes OP1 have a depth larger than that of the second contact holes OP2, the third contact holes OP3, and the fourth contact holes OP4. The bottom portions of the first contact structures SC1 formed in the first contact holes OP1 are lower than the bottom portions of the second contact structures SC2, the third contact structures SC3, and the fourth contact structures SC4 respectively formed in the second contact holes OP2, the third contact holes OP3, and the fourth contact holes OP4. By extending the first contact structures SC1 deeper into the substrate 100, the contact area between the first contact structures SC1 and the end portions of the active regions 102 may be increased, so that a lower contact resistance and improved contact quality may be achieved.

According to an embodiment of the present invention, as illustrated in FIG. 13 and FIG. 15, the bottom portions of the first contact structures SC1 are lower than the bottom surfaces of the first recesses R1. The bottom portions of the second contact structures SC2, the third contact structures SC3, and the fourth contact structures SC4 are not lower than the bottom surfaces of the second recesses R2. In other words, the bottom portions of the first contact structures SC1 are lower than the top surfaces of the middle portions of the active regions 102 recessed by the first recesses R1. The bottom portions of the second contact structures SC2, the third contact structures SC3, and the fourth contact structures SC4 are not lower than the top surfaces of the middle portions of the active regions 102 recessed by the second recesses R2. The bottom portion of the semiconductor layer 122 of the first bit line structure BL1 located within the first recesses R1 is higher than the bottom portions of the first contact structures SC1. The bottom portion of the semiconductor layer 122 of each second bit line structure BL2 located within the second recesses R2 is lower than the bottom portions of the second contact structures SC2, the third contact structures SC3, and the fourth contact structures SC4.

According to an embodiment of the present invention, as illustrated in FIG. 14, the first contact structures SC1 and the second contact structures SC2 are alternately arranged between isolation spacers 156. The bottom portions of the first contact structures SC1 and the second contact structures SC2 extend to alternating different depths in the substrate 100, lower than the top surfaces of the insulating cap layer 138 of the gate structures 106 and higher than the top surfaces of the metal layer 134 of the gate structures 106. When a polysilicon layer 136 is disposed between the metal layer 134 and the insulating cap layer 138 of the gate structures 106, the bottom portions of the first contact structures SC1 and the second contact structures SC2 are higher than the top surface of the polysilicon layer 136.

According to an embodiment of the present invention, as illustrated in FIG. 15 and FIG. 16, the bottom portions of the second contact structures SC2, the third contact structures SC3, and the fourth contact structures SC4 extend to approximately the same depth in the substrate 100 and are flush to each other.

The widths of the first contact structures SC1, the second contact structures SC2, the third contact structures SC3, and the fourth contact structures SC4 are determined by the first contact holes OP1, the second contact holes OP2, the third contact holes OP3, and the fourth contact holes OP4, respectively. According to an embodiment of the present invention, along the first direction D1, the width of the first contact structures SC1 is larger than the width of the third contact structures SC3. According to an embodiment of the present invention, along the first direction D1, the widths of the contact structures SC2, the third contact structures SC3, and the fourth contact structures SC4 are approximately the same. According to an embodiment of the present invention, the width of the first contact structures SC1 is larger than the widths of the second contact structures SC2, the third contact structures SC3, and the fourth contact structures SC4.

Please continue to refer to FIG. 12, FIG. 13, FIG. 14, FIG. 15, and FIG. 16. According to an embodiment of the present invention, the semiconductor structure provided by the invention may be utilized to manufacture dynamic random access memory (DRAM) with stacked capacitors. For example, after forming the contact pads SNP, an insulating material 172 is formed over the substrate 100 to fill the spaces between the contact pads SNP, thereby creating a planar surface for subsequent manufacturing steps and ensuring electrical isolation between the contact pads SNP. Subsequently, a plurality of capacitor structures CAP are formed respectively on the contact pads SNP. Each capacitor structure CAP includes a bottom electrode BE extending vertically on the contact pad SNP, a dielectric layer IL covering along the sidewalls and top surface of the bottom electrode BE, and a top electrode TE on the dielectric layer TL and capacitively coupled to the bottom electrode BE through the dielectric layer IL. Based on the design needs, the bottom electrode BE may be a solid cylindrical structure with a closed bottom portion (as shown in FIG. 13, FIG. 14, and FIG. 15), or may be a hollow cylindrical structure to allow part of the top electrode TE filling into the inner cavity in the bottom electrode BE thereby increasing the capacitive coupling area between the bottom electrode BE and the top electrode TE. According to an embodiment of the present invention, a supporting layer 176 may be provided between the capacitor structures CAP, extending laterally and directly contacting the sidewalls of the bottom electrodes BE to support the bottom electrodes BE. According to an embodiment of the present invention, an etching stop layer 174 may be formed on the insulating material 172. The bottom portions of the bottom electrodes BE extend through the etching stop layer 174 to directly contact the contact pads SNP.

The insulating material 172, the etch stop layer 174, the supporting layer 176, and the dielectric layer TL respectively include dielectric materials. The bottom electrodes BE and the top electrodes TE respectively include conductive materials. The bottom electrodes BE are electrically connected to the end portions of the active regions 102 via the contact pads SNP and the first plug structures SC1, the second plug structures SC2, the third plug structures SC3, or the fourth plug structures SC4, such that the gate structures 106 and the bit line structures BL control the storage or release of charges into or from the capacitor structures CAP for data storage.

In summary, the semiconductor structure and the method for forming the semiconductor structure provided by the present invention may form contact structures of varying desired depths conveniently by forming contact holes with different depths, thereby enhancing the contact quality between the contact structures and the active regions of the transistors. The dynamic random access memory (DRAM) based on the semiconductor structure of the present invention may have improve device performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate comprising a plurality of active regions;
a plurality of gate structures extending along a first direction and intersecting the plurality of active regions to divide each of the plurality of active regions into a middle portion and two end portions;
a plurality of bit line structures extending along a second direction and electrically connected to the middle portions of the active regions, wherein the first direction and the second direction are perpendicular, an outside part of the plurality of bit line structures comprises a first bit line structure, an inside part of the plurality of bit line structures comprises a second bit line structure; and
a plurality of first contact structures and a plurality of second contact structures alternatively and separately disposed at an outer side of the first bit line structure along the second direction and electrically connected to the end portions of the active regions, wherein bottom portions of the first contact structures are lower than bottom portions of the second contact structures.

2. The semiconductor structure according to claim 1, wherein the bottom portions of the second contact structures are not lower than top surfaces of the middle portions of the active regions, the bottom portions of the first contact structures are lower than the top surfaces of the middle portions of the active regions.

3. The semiconductor structure according to claim 1, further comprising a dummy bit line structure at the outer side of the first bit line structure, wherein the first contact structures and the second contact structures are alternatively disposed along the second direction between first bit line structure and the dummy bit line structure.

4. The semiconductor structure according to claim 1, wherein the dummy bit line is electrically isolated from each of the plurality of active regions.

5. The semiconductor structure according to claim 1, wherein each of the gate structures comprises:
a gate dielectric layer;
a metal layer disposed on the gate dielectric layer; and
an insulating cap layer disposed on the metal layer, wherein the bottom portions of the first contact structures are higher than a top surface of the metal layer.

6. The semiconductor structure according to claim 5, wherein each of the gate structures further comprises a polysilicon layer disposed between the metal layer and the insulating cap layer, wherein the bottom portions of the first contact structures are higher than a top surface of the polysilicon layer.

7. The semiconductor structure according to claim 5, wherein the bottom portions of the second contact structures are lower than a top surface of the insulating cap layer.

8. The semiconductor structure according to claim 1, further comprising a plurality of third contact structures and a plurality of fourth contact structures alternatively and separately disposed along the second direction between an inner side of the first bit line structure and the second bit line structure, wherein the third contact structures are aligned to the first contact structures along the first direction, the fourth contact structures are aligned to the second contact structures along the first direction, and bottom portions of the third contact structures and bottom portions of the fourth contact structures are higher than the bottom surfaces of the first contact structures.

9. The semiconductor structure according to claim 8, wherein the bottom portions of the second contact structures, the bottom portions of the third contact structures, and the bottom portions of the fourth contact structures extend to a same depth in the substrate.

10. The semiconductor structure according to claim 1, further comprising a plurality of capacitor structures respectively disposed on the first contact structures and the second contact structures.

11. A semiconductor structure, comprising:
a substrate comprising a plurality of active regions;
a plurality of gate structures extending along a first direction and intersecting the plurality of active regions;
a plurality of spacer structures disposed on the gate structures; and
a plurality of first contact structures and a plurality of second contact structures alternatively disposed between the spacer structures along a second direction and electrically connected to the active regions, wherein bottom portions of the first contact structures are lower than bottom portions of the second contact structures.

12. The semiconductor structure according to claim 11, wherein each of the gate structures comprises:
a metal layer;
a gate dielectric layer disposed between the substrate and the metal layer; and
an insulating cap layer disposed on the metal layer, wherein the bottom portions of the first contact structures are higher than a top surface of the metal layer.

13. The semiconductor structure according to claim 12, wherein each of the gate structures further comprises a polysilicon layer disposed between the metal layer and the insulating cap layer, wherein the bottom portions of the first contact structures are higher than a top surface of the polysilicon layer.

14. The semiconductor structure according to claim 12, wherein the bottom portions of the second contact structures are lower than a top surface of the insulating cap layer.

15. A semiconductor structure, comprising:
a substrate comprising a plurality of active regions;
a plurality of gate structures extending along a first direction and intersecting the plurality of active regions;
a plurality of bit line structures extending along a second direction and electrically connected to the active regions, wherein the first direction and the second direction are perpendicular, an outside part of the plurality of bit line structures comprises a first bit line structure, an inside part of the plurality of bit line structures comprises a second bit line structure;
at lease a first contact structure disposed at an outer side of the first bit line structure; and
a plurality of third contact structures disposed at an inner side of the first bit line structure and between the second bit line structures, and aligned to the first contact structure along the first direction, wherein in a cross-sectional view, a bottom portion of the first contact structure is lower than bottom portions of the third contact structures, and a width of the first contact structure is larger than a width of the third contact structures.

16. The semiconductor structure according to claim 15, further comprising:
at least a second contact structure disposed at the outer side of the first bit line structure; and
a plurality of fourth contact structures disposed between the inner side of the first bit line structure and the second bit line structure and aligned to the second contact structure along the first direction, wherein in another cross-sectional view, a bottom portion of the second contact structure and bottom portions of the fourth contact structures are at a same height.

17. The semiconductor structure according to claim 15, further comprising a dummy bit line structure at the outer side of the first bit line structure, wherein the first contact structures is disposed between first bit line structure and the dummy bit line structure.

18. The semiconductor structure according to claim 15, wherein each of the gate structures comprises:
a gate dielectric layer;
a metal layer disposed on the gate dielectric layer; and
an insulating cap layer disposed on the metal layer, wherein the bottom portion of the first contact structure is higher than a top surface of the metal layer.

19. The semiconductor structure according to claim 18, wherein each of the gate structures further comprises a polysilicon layer disposed between the metal layer and the insulating cap layer, wherein the bottom portion of the first contact structure is higher than a top surface of the polysilicon layer.

20. The semiconductor structure according to claim 18, wherein bottom portions of the third contact structures are lower than a top surface of the insulating cap layer.
